(19) United States
(12) Patent Application Publication
(10) Pub. No.: US 2005/0275027 A1
(43) Pub. Date: Dec. 15, 2005

(54) ESD protection for integrated circuits

(75) Inventor: Shekar Mallikarjunaswamy, San Jose, CA (US)

Correspondence Address: LADAS & PARRY, 5670 WILSHIRE BOULEVARD, SUITE 2100, LOS ANGELES, CA, 90036-5679, US

(73) Assignee: MICREL, Incorporated, San Jose, CA (US)

(21) Appl. No.: 10/658,181

(22) Filed: Sep. 9, 2003

(51) Int. Cl. H01L 23/62

(52) U.S. Cl. 257/355

(57) ABSTRACT

Electrostatic discharge protection for integrated circuits, particularly for enhancing electrostatic discharge protection performance for Input-output cells and power supply clamps used in CMOS and BiCMOS IC technologies is described. A P-type, implantation region, or layer, referred to as “P-deep,” in both N-MOSFET and P-MOSFET devices is provided to enhance electrostatic discharge protection performance. Parasitic transistor gain is enhanced by providing the P-deep region subposing the drain contact. Exemplary embodiments for N-type and P-type MOSFETs, MOSFETs with surface diodes, MOSFETS with SCRs, and push-pull Input-output CMOS circuits are described.

### CROSS-REFERENCE TO RELATED APPLICATIONS

Not applicable.

### STATEMENT REGARDING FEDERALLY SPONSORED RESEARCH OR DEVELOPMENT

Not applicable.

### REFERENCE TO AN APPENDIX

Not applicable.

### BACKGROUND

### TECHNICAL FIELD

This disclosure relates generally to integrated circuits and more particularly to electrostatic discharge protection for integrated circuits.

### DESCRIPTION OF RELATED ART

Electrostatic discharge (“ESD”) is a well known concern with respect to the design and implementation of integrated circuits (“IC” or “chip”). ESD events occur when very large electrical spikes, potentially reaching thousands of volts, occur on an input-output (“I/O”) terminal, “pad,” of the chip which is designed for an operating voltage of just a few volts. Such ESD spikes can damage or destroy the IC components, rendering it defective or useless. Therefore, ICs are frequently designed to provide some sort of protection against ESD events.

The ESD problem is particularly egregious in metal-oxide-semiconductor (“MOS”) and complementary-metal-oxide-semiconductor (“CMOS”) integrated circuits. FIG. 1C (Prior Art) is an electrical schematic block diagram illustrating a typical input-output (“I/O”) pad and VCC pad scheme. While exemplary structures, elements, and devices are discussed in detail hereinafter, it will be recognized by those skilled in the art that specific implementations will vary depending on the specific design criteria, e.g., size, operating voltage, “VCC,” and current requirements, and the like, and fabrication processes for any NMOS, PMOS, CMOS, and BiCMOS type integrated circuit implementations; no limitation on the scope of the invention is intended by the inventor by use of the following examples, nor should any be implied therefrom.

It is known in the art to use surface diodes, Zener diodes and Schottky diodes to protect against IC damage due to ESD events; see e.g. U.S. Pat. No. 5,412,527 (Husher), assigned to the common assignee hereof.

FIGS. 1A (Prior Art) and 1B (Prior Art) illustrate conventional MOSFET structures 100N, 100P, respectively; depicting a pair of a larger MOSFET array commonly found in ICs. In conventional input-output (“I/O”) cells of a CMOS chip, it is know to use a pull-up, field effect transistor (“FET”)—see e.g., a P-type dopant source/drain, P-channel, MOSFET (hereinafter “P-MOSFET” for short) 100P—and a pull-down transistor—see e.g., a N-type dopant source/drain, N-channel, MOSFET (hereinafter “N-MOSFET” for short) 100N—in push-pull circuit configurations either to drive a signal off-chip or to receive and condition external inputs to the chip circuitry. It is known to combine the push-pull transistor pair with the circuitry shown by Husher, supra, to protect the internal IC circuitry from ESD events which can be for example as high as 200 Volts in a machine model or 2000 Volts in a human body model.

Referring again to FIG. 1A, with a N-MOSFET structure 100N—with “D” designating drain region and contact, “G” designating gate region and contact, and “S/B” designating source/body region and contact—used in I/O cells, ESD event device breakdown occurs along the N+ doped common drain region 101 and gate polysilicon 103, 103′ interfaces at the epitaxial layer, “P-epi/P-well” 105, surface 105′. Similarly referring to FIG. 1B, with a P-MOSFET structure 100P, ESD event device breakdown occurs along the P+ doped drain region 107 to gate polysilicon region 103, 103′ interfaces 109, 109′.

However, newer electronic appliance applications, such as allowing computer peripheral plug-in during computer operation—also known as “hot plug-ins” (e.g., plugging a printer into a laptop computer without first turning off the appliances), “hot swaps” (e.g., exchanging a floppy disk drive for a CD drive), USB port On-The-Go uses, power over an Ethernet connection, and the like, all have a potential for even much higher ESD events, e.g., up to 15,000 Volts, human body model. Thus, these newer appliances have a need for IC devices having concomitant ESD ratings.

### BRIEF SUMMARY

The basic aspects of the invention generally provide circuitry and IC device structures for improving ESD protection for integrated circuits.

In one aspect, an exemplary embodiment of the present invention provides semiconductor MOSFET structure having improved ESD tolerance, the structure including: a semiconductor substrate having an active device surface; in said surface, a MOSFET source region and a MOSFET drain region separated by a channel region; a P-type dopant region subjacent said drain region and having a dopant concentration and predetermined dimensions such inherent parasitic transistor gain of said MOSFET structure is increased.

In another aspect, an exemplary embodiment of the present invention provides an integrated circuit ESD protection device for an IC I/O pad, the device including: a N-MOSFET; a P-MOSFET, wherein said N-MOSFET and P-MOSFET are connected in a push-pull configuration with drain regions thereof connected to said I/O pad; and both said N-MOSFET and said P-MOSFET including a P-type dopant region substantially subjacent respective the drain regions of each such that P-MOSFET parasitic PNP transistor gain and N-MOSFET parasitic NPN transistor gain is increased thereby.

In another aspect, an exemplary embodiment of the present invention provides an ESD protection circuit for an IC having at least one I/O pad and at least one VCC pad having a electrically grounded ESD protection device connected thereto, the circuit including: a N-GCMOSFET having a first drain region connected to said I/O pad, a first gate region connected to electrical ground, and a first source region connected to electrical ground; and a P-GCMOSFET having a second drain region connected to said I/O pad, a second gate region connected to said VCC pad, and a second source region connected to said VCC pad, wherein said first drain region has a P-type dopant region substantially subjacent thereto for enhancing parasitic NPN transistor gain thereof, and said second drain region has a P-type dopant region substantially subjacent thereto for enhancing parasitic PNP transistor gain thereof.

In another aspect, an exemplary embodiment of the present invention provides a N-channel MOSFET structure for ESD device, the structure including: a P-doped substrate having an epitaxial layer for forming active device elements therein; and within said epitaxial layer, a N+ doped source region; a N+ drain region; a P-doped channel region between the source region and the drain region; a gate superjacent the channel; an N-doped well region beneath said drain region having a width dimension less than a width dimension of said drain region; and a P-doped deep region, beneath said drain region and adjacent said well region, having a dopant concentration greater than said P-doped channel region, wherein said P-doped deep region increases gain of a parasitic lateral NPN transistor formed by said source region, said channel region and said drain region and lowers triggering voltage of said MOSFET.

In another aspect, an exemplary embodiment of the present invention provides a P-channel MOSFET structure for an ESD protection circuit, the structure including: a P-doped substrate having an epitaxial layer; a N-doped well in said epitaxial layer for forming active device elements therein; and within said N-doped well, a P+ doped source region; a P+drain region; a N-doped channel region between the source region and the drain region; a gate superjacent the channel; and a P-doped deep region, beneath said drain region and adjacent said well region, wherein said P-doped deep region increases gain of a parasitic PNP transistor formed by said drain region, N-doped well region and said epitaxial layer and lowers triggering voltage of said MOSFET.

In another aspect, an exemplary embodiment of the present invention provides a MOSFET structure for an ESD protection circuit, the structure including: a substrate having an epitaxial layer forming an active device surface; at least two MOSFETs proximate said surface, each MOSFET having a first dopant type drain region wherein said drain regions are adjacent and separated by a region of said surface and forming diode poles thereby; and a second dopant type deep region at said region of the surface, wherein said deep region has a depth from said surface into said epitaxial layer greater than a depth of each of said drain regions such that an ESD spike causes a diode breakdown to the epitaxial layer before affecting the MOSFETs.

In another aspect, an exemplary embodiment of the present invention provides a MOSFET structure for an ESD protection circuit employing an SCR, the structure located in an epitaxial layer of a first dopant type of a substrate, said epitaxial layer having an active device surface, the structure including: a first MOSFET of a second dopant type located proximate said surface and having a first drain region of the second dopant type; a second MOSFET of the second dopant type and located proximate said surface and having a second drain region of the second dopant type proximate said first drain region; a drain contact electrically connecting said first drain region and said second drain region; a surface contact region abutting said drain contact and separating said first drain region said second drain region, said surface region having said first dopant type; subjacent the surface contact region and within said epitaxial layer, a well of said second dopant type, wherein said well is subjacent both said first drain region and said second drain region; and within said well, a deep region of P-type ion dopant, wherein said deep region is subjacent both said first drain region, said second drain region, and said surface contact region, wherein said deep region dimensions and concentration of the P-type ion are predetermined for achieving a desired SCR punch-through voltage via tuning breakdown fields and improving structure inherent bipolar transistor gain accordingly.

In another aspect, an exemplary embodiment of the present invention provides a BiCMOS technology N-MOSFET structure for ESD protection circuits, the structure including: a P ion doped substrate; an N ion doped epitaxial layer superjacent said substrate, said epitaxial layer having an upper surface distal from said substrate; a buried isolation layer; a P ion doped well subjacent in said upper surface; a N+ ion doped source region subjacent said surface; a N+ ion doped drain region subjacent said surface; a region of said well forming a P ion channel region at said surface between said source region and said drain region; a gate structure superposing said channel region; and subjacent said drain region and within said well, a P ion doped deep region, said deep region having an ion concentration greater than ion concentration of said well, such that lateral bipolar parasitic NPN transistor of said structure is provided with increased gain by the deep region.

In another aspect, an exemplary embodiment of the present invention provides a BiCMOS technology P-MOSFET structure for ESD protection circuits, the structure including: a P ion doped substrate; an N ion doped epitaxial layer superjacent said substrate, said epitaxial layer having an upper surface distal from said substrate; a buried isolation layer; a N ion doped well subjacent in said upper surface; a P+ ion doped source region subjacent said surface; a P+ ion doped drain region subjacent said surface; a region of said well forming a N ion channel region at said surface between said source region and said drain region; a gate structure superposing said channel region; and subjacent said drain region and within said well, a P ion doped deep region, said deep region having an ion concentration substantially equal to or greater than ion concentration of said drain region, such that vertical bipolar parasitic PNP transistor of said structure is provided with increased gain by the deep region.

In another aspect, an exemplary embodiment of the present invention provides a BiCMOS technology structure for a push-pull I/O ESD protection circuit employing an SCR, the structure located in an epitaxial layer of a first dopant type of a substrate of a second dopant type, said epitaxial layer having an active device surface, the structure including: a first dopant type buried layer segregating said epitaxial layer and said substrate; a second dopant type first well within said epitaxial layer and subjacent said surface; a second dopant type second well within said epitaxial layer and subjacent said surface; a first dopant type third well within said epitaxial layer and subjacent said surface, such that third well is adjacently between said first well and said second well; a first MOSFET of the first dopant type located within said first well proximate said surface and having a first drain region of the first dopant type and having a predetermined drain width for superjacently spanning a first area of said surface encompassing surface regions of both said first well and said third well; a second MOSFET of the first dopant type and located within said second well proximate said surface and having a second drain region of the first dopant type and having a predetermined drain width for superjacently spanning a second area of said surface encompassing surface regions of both said third well and said second well; a drain contact electrically connecting said first drain region and said second drain region; a surface contact region abutting said drain contact and separating said first drain region said second drain region, said surface region having said second dopant type; within said third well, a deep region of P-type ion dopant, wherein said deep region is subjacent both said first drain region, said second drain region, and said surface contact region, wherein said deep region dimensions and concentration of the P-type ion are predetermined for achieving a desired SCR punch-through voltage via tuning breakdown fields and improving structure inherent bipolar transistor gain accordingly.

In another aspect, an exemplary embodiment of the present invention provides an extended drain N-channel MOSFET structure including: a P-type substrate; in said substrate at least one MOSFET structure having extended and enhanced drain region devices for providing reduced on-resistance at a surface region of said substrate, said MOSFET structure including an N+ doped drain region in an N-type well region; and a P-deep region subjacent the N-well containing the drain region, said P-deep region having geometry and a dopant concentration such that said P-deep region increases gain of a parasitic lateral NPN transistor and lowers triggering voltage of said MOSFET.

The foregoing summary is not intended to be inclusive of all aspects, objects, advantages and features of the present invention nor should any limitation on the scope of the invention be implied therefrom. This Brief Summary is provided in accordance with the mandate of 37 C.F.R. 1.73 and M.P.E.P. 608.01 (d) merely to apprise the public, and more especially those interested in the particular art to which the invention relates, of the nature of the invention in order to be of assistance in aiding ready understanding of the patent in future searches.

### BRIEF DESCRIPTION OF THE DRAWINGS

FIG. 1A (Prior Art) is a cross-sectional, elevation view, schematic of a conventional N-channel MOSFET.

FIG. 1B (Prior Art) is a cross-sectional, elevation view, schematic of a conventional P-channel MOSFET.

FIG. 1C (Prior Art) is an electrical schematic block diagram illustrating a typical input-output (“I/O”) pad and VCC pad scheme.

FIG. 2A is a cross-sectional, elevation view, schematic of a N-channel MOSFET structure in accordance with an exemplary embodiment of the present invention.

FIG. 2B is a cross-sectional, elevation view, schematic of a P-channel MOSFET structure in accordance with an exemplary embodiment of the present invention.

FIG. 3 is a push-pull I/O circuit diagram in accordance with another exemplary embodiment of the present invention employing MOSFETs using the structure 200N of FIG. 2A and structure 200P FIG. 2B.

FIG. 4 is a cross-sectional, elevation view, schematic of a N-channel MOSFET structure including a surface diode/Zener diode in another exemplary embodiment in accordance with the present invention.

FIG. 5 is a N-channel MOSFET structure with integrated silicon controlled rectifier (“SCR”) exemplary embodiment in accordance with the present invention in a cross-sectional, elevation view.

FIG. 6A is a cross-sectional, elevation view, schematic of another N-channel MOSFET structure used typically in BiCMOS technology in another exemplary embodiment of the present invention.

FIG. 6B is a cross-sectional, elevation view, schematic of another P-channel MOSFET structure used typically in BiCMOS technology in another exemplary embodiment of the present invention.

FIG. 7 is a cross-sectional, elevation view, schematic of a BICMOS structure with integrated silicon controlled rectifier in another exemplary embodiment in accordance with the present invention.

FIG. 8 is a cross-sectional, elevation view, schematic of an extended drain N-channel MOSFET structure in another exemplary embodiment in accordance with the present invention.

FIG. 9 is a cross-sectional, elevation view, schematic of a single N-MOSFET structure in another exemplary embodiment in accordance with the present invention.

Like reference designations represent like features throughout the drawings. The drawings in this specification should be understood as not being drawn to scale unless specifically annotated as such.

### DETAILED DESCRIPTION

In general, the present invention uses at least one P-type, implantation region, or layer, referred to hereinafter as “P-deep,” in both NMOS and PMOS devices to enhance ESD protection performance. The present invention is particularly suited to enhancing ESD protection performance for I/O cells and power supply clamps used in CMOS and BiCMOS IC technologies.

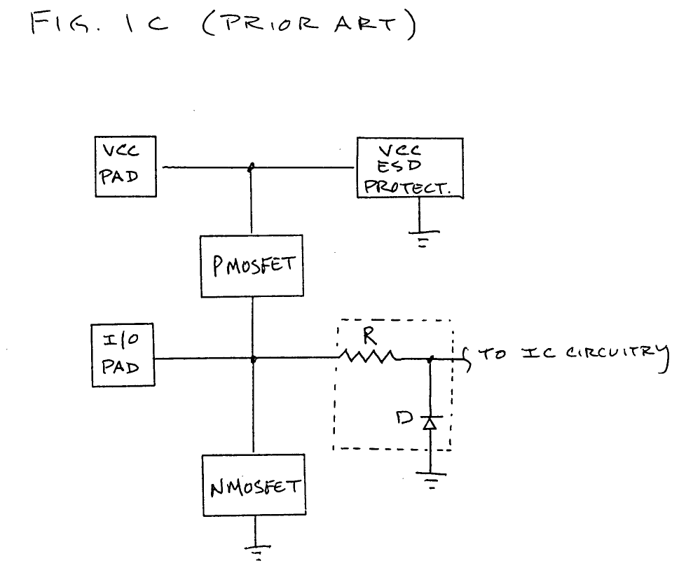

A cross-sectional, elevation view schematic of a pair of adjacent N-MOSFET 200N structures in accordance with an exemplary embodiment of the present invention is shown in FIG. 2A. It should be recognized that this drawing represents a small region of input/output structures of a complete IC, viz., part of an array of I/O cells, or the like as would be known in the art. It should be recognized that many publications describe the details of common techniques used in the fabrication process of integrated circuit components. See, e.g., Wolf, S., Silicon Processing for the VLSI Era, copyright 1990, Lattice Press; Sze, S. M., VLSI Technology, copyright 1988, McGraw-Hill; Ghandhi, S. K., VLSI Fabrication Principles, copyright 1983, John Wiley & Sons; or Semiconductor & Integrated Circuit Fabrication Techniques, Reston Publishing Co., Inc., copyright 1979 by the Fairchild Corporation. Those known manner techniques are generally employed in the fabrication of the structure of the present invention except in the steps required to accomplish the goals of the present invention; as such, an in depth description of known manner steps is unnecessary to an understanding of the present invention. Moreover, the individual steps of such a process can be performed using commercially available integrated circuit fabrication machines. See, e.g., Chapman, B., Glow Discharge Processes/Sputtering and Plasma Etching, copyright 1980, John Wiley & Sons. As specifically helpful to an understanding of the present invention, approximate technical data are set forth based upon current technology. Future developments in this art may call for appropriate adjustments as would be obvious to one skilled in the art. It will be intuitively obvious to a person skilled in the art that the invention taught herein will have wide applicability to integrated circuit fabrication processes; this description relies on an exemplary implementation of industrial applicability and no limitation on the scope of the invention is intended nor should any be implied therefrom.

On a P-type doped substrate 201, having a surface 203, a P-type doped epitaxial layer 205 (“P-epi”) is formed wherein IC active devices will be fabricated in a known manner. Using conventional, grown field oxide (“FOX”) regions 207, 207′ for masking, a P-type doped “P-well” 209 is formed. Relatively high concentration, “designated N+,” N-type doped source, “S,” regions 211, 211′ and a common drain, “D,” region 213 are formed within the P-well 209. Also conventionally, respective transistor gates, “G,” 217, 217′ are formed in respective gate polysilicon 219, 219′ superjacent epitaxial surface 205′ and the N-MOSFET source-drain N-channel regions in the epitaxial P-well 209, respectively. In a known manner commonly referred to as “Metal 1” process steps, conductor traces 221, 221′, 215 and electrical contacts are formed for respective source/body, “S/B,” and drain regions of the MOSFET structure 200. P+ doped body regions 220, 220′ complete the traditional elements of the dual N-MOSFET cell structure 200N.

“N-well” 223 is formed in the P-well 209 subjacent the drain contact 215, bridging the drain to the P-epi layer 205. This deep N-well 223 facilitates reduction of current density in the N+ regions and reduction of heating of the contacts to avoid metal spiking into the silicon, which would result in junction leakage or short. Generally, the cross-sectional width of the deep N-well 223 is in the range of approximately two to three times the width of the drain contact 215 surface region. The N-type ion concentration is less than that of the source/drain concentration by a factor in the approximate range of 1E3 to 1E4.

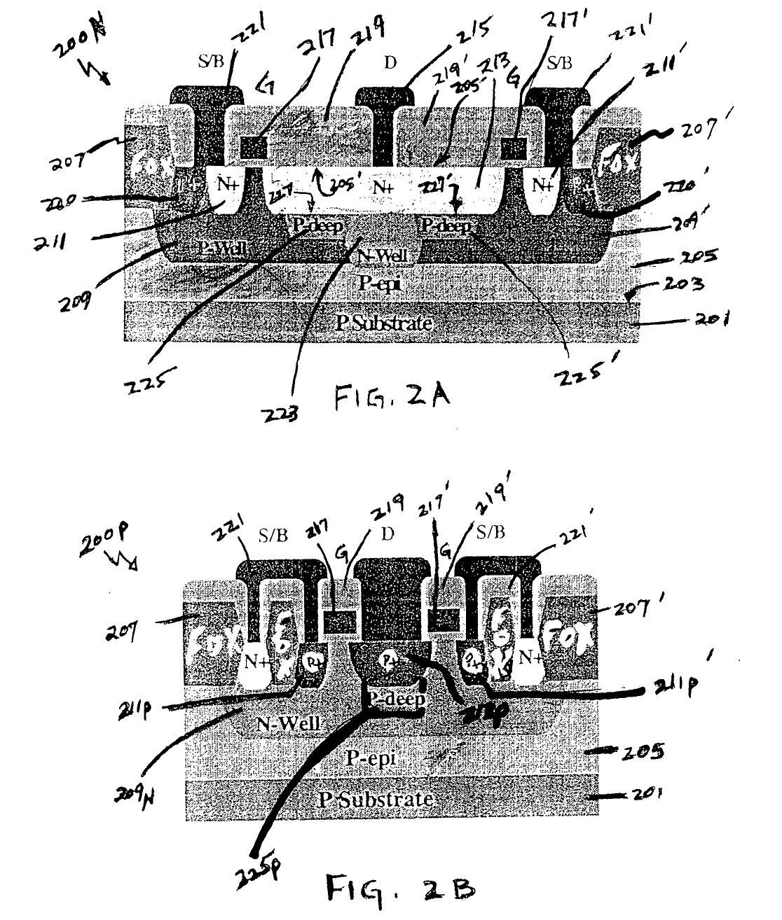

A deep implant of P-type dopant is made in order to form “P-deep” regions 225, 225′. While implant concentration will be process specific, generally it may be considered that the surface concentration of the dopant ions in the P-deep regions 225, 225′ should be approximately an order of magnitude greater than that of the dopant ions at the P-well 209 surface concentration. Similarly, the respective junction depth of the P-well 209 and P-deep regions 225, 225′ will be process dependent. In general, as will be discussed in more detail hereinafter, particularly with respect to FIG. 3, the design goal is to improve parasitic transistor performance to enhance ESD protection. Note, particularly in the case of a push-pull I/O circuit embodiment, that this is directly contrary to conventional wisdom, which seeks to suppress parasitic transistor gain.

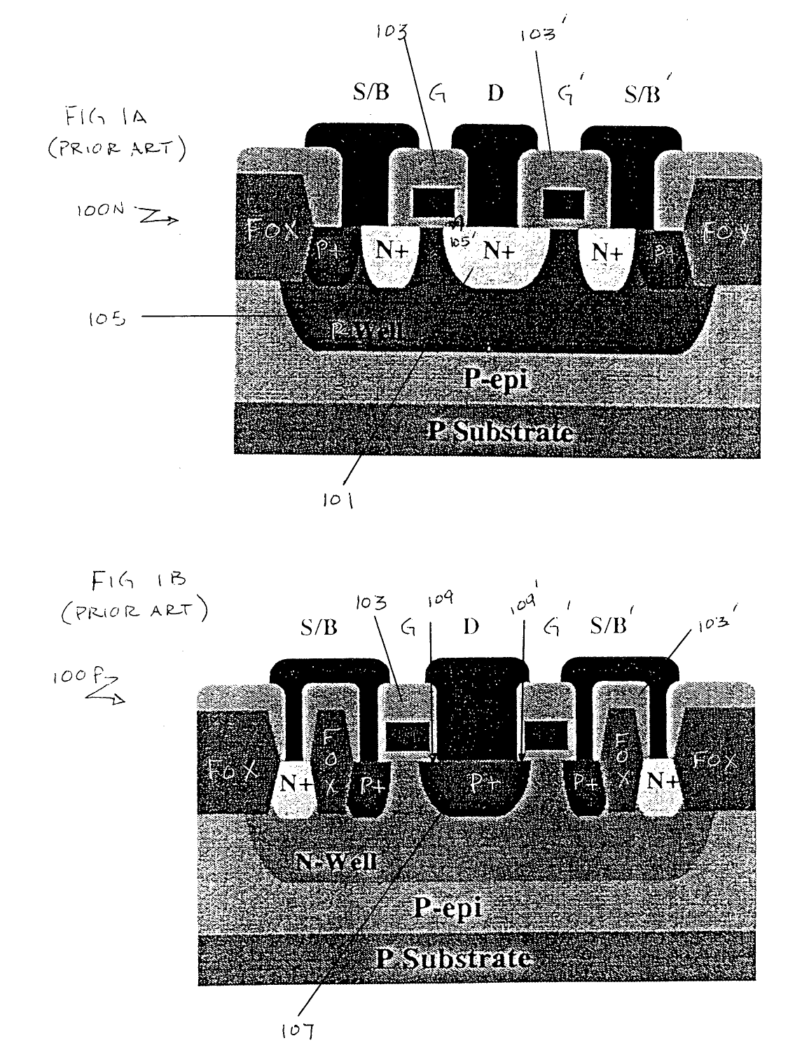

The P-deep regions 225, 225′ are formed subjacently to the drain region 213 and adjacently to the sub-drain N-well region 223. That is, the deep P-dopant implant is done proximate to both the N+ drain region and the N-well region-to-drain interface. This structure produces high electric field areas across the N+ drain 213 to P-deep interfaces 227, 227′. Thus, heat from current flow under junction breakdown conditions during an ESD event is positioned distally to the drain contact to avoid contact metal spiking. There is a higher drain-to-substrate inherent capacitance and enhanced parasitic NPN transistor gain in breakdown of the structure of FIG. 2A compared to FIG. 1A, providing a lower trigger voltage for the N-MOSFETs, and enhancing ESD protection. This will be explained further with respect to FIG. 3.

It is recognized and noted that while higher drain-to-substrate capacitance is good for ESD protection, it affects rise-time and fall-time on the input-output pads. This should be taken into consideration for any specific design implementation. Nonetheless, the present invention has been found to greatly scalable for appliances where high ESD immunity is necessary. In most of the embodiments described herein, because the P-deep region is incorporated within the basic 225, 225′ traditional MOSFET structure, there is no requirement for using of valuable epitaxial surface area.

Turning to FIG. 2B, a structure 200P is illustrated for P-MOSFETs in accordance with another embodiment of the present invention. As would be known in the art, for a PMOS device the implant dopants for the traditional FET elements, the epi-well 209_{N}, the source regions 211_{P}, 211_{P} and drain region 213_{P}, are the opposite of the NMOS devices of FIG. 2A. Another difference is that the drain region 213_{P} is not expanded in width as was the case in the NMOS devices of FIG. 2A. Therefore, in accordance with this exemplary embodiment, a single P-deep implant region 225_{P} can be formed subjacently to the P-type drain region 213_{P} directly in the N-well 209_{P}. For P-MOSFETs, the P-deep region provides an improved parasitic PNP transistor gain that enhances ESD protection.

Now turning to FIG. 3, an equivalent circuit for a pull-up P-MOSFET and pull-down N-MOSFET I/O circuit 300 employing the present invention is depicted. The FIGURE is illustrative of one I/O pad 301 of a chip having many such input-outputs for the associated chip circuitry (not shown other than “To ckt.” node 303). The chip operating voltage, VCC, is provided via a conventional VCC pad 305. The VCC pad 305 is shown having an ESD protection circuit comprising a conventional N-channel MOSFET 307—viz., such as shown in FIG. 1A—in a source-gate-coupled, “GC,” grounded-gate, “GG,” configuration, with its gate grounded via resistor R1; see also, FIG. 2A, 200N. A drain to P-well to source, lateral, bipolar, parasitic NPN transistor of the MOSFET 307 is shown in phantom-line.

A P-deep, P-MOSFET 200P, in accordance with the structural embodiment described above with respect to FIG. 2B, connects the VCC pad 305 and the I/O pad 301. The P-MOSFET 200P is gate-coupled, with the gate, G, electrically tied to the VCC pad, via node 309, and to the source, S. The drain, D, is electrically connected, via node 311, to the I/O pad 301. This P-GCMOSFET 200P has a drain-to-well-to-epi/substrate bipolar parasitic PNP transistor 313 shown in phantom line. Effectively, the parasitic PNP transistor 313 has a grounded collector, C, since the P-type substrate is electrical ground, a base, B, derived from the N-well body of the P-GCMOSFET 200P electrically connected to the source, S, and emitter, E, derived from the P-GCMOSFET 200P drain, D. Addition of the P-deep implant 225_{P}, FIG. 2B, subjacent the drain region 213_{P} of the P-GCMOSFET 200P effectively increases the gain of the parasitic PNP transistor 313.

Also electrically tied via node 311 to the I/O pad 309 is the drain, D, of a P-deep, N-GCMOSFET 200N as shown in FIG. 2A. The gate, G, of transistor 200N is connected to ground via a resistor R2. The source, S, of transistor 200N is connected directly to ground and effectively to the gate, G, via the resistor R2. The N-GC-MOSFET 200N has a lateral, bipolar, parasitic NPN transistor 315 deriving its emitter, E, from the N-MOSFET 200N source, S, its collector from the drain, D, and its base, B, at ground from the P-well.

This push-pull arrangement of FIG. 3 connected to the I/O pad 301 via node 311 thus employs the structures shown in FIGS. 2A and 2B. As in FIG. 2A, the parasitic NPN transistor 315, FIG. 3, is formed by N-type drain 213, grounded N-type source 211, and P-well 209. In FIG. 2B, the parasitic PNP transistor 313 is formed by P-deep region 225_{P}, N-well 209_{P}, P-epi205/P-substrate 201.

For P-MOSFET implementations, by use of P-deep implant, the effective base width of parasitic transistors is reduced since the substrate-to-drain spacing is reduced. For N-MOSFET implementations, the P-deep region enhances capacitance and parasitic NPN gain during breakdown.

In operation, when the I/O pad 301 experiences an ESD, the P-type drain, D, acting as the emitter, E, to source, S, acting as base, B, forms a diode of the P-GCMOSFET 200P that gets forward biased such that part of the ESD event current is shunted to ground via the P-epi 205 and substrate 201 layers. Note also, that part of the current from the ESD event on the I/O pad 301 will flow through the P-MOSFET channel to pad 305, through the parasitic PNP transistor 313 of the GC-MOSFET 200P to ground via the ESD protection circuit on the VCC pad 305, as its parasitic NPN transistor is turned ON, and through N-GC-MOSFET 200N; the parasitic NPN transistor 315 of GC-MOSFET 200N turns on during an ESD event. Effectively, the P-deep region 225, 225′ increases the inherent capacitance to ground of the N-GCMOSFET 200N. Again, ESD current is shunted from node 311 to ground.

Thus, three paths are conducting ESD current to ground and away from node 303 and the internal circuitry of the integrated circuit chip.

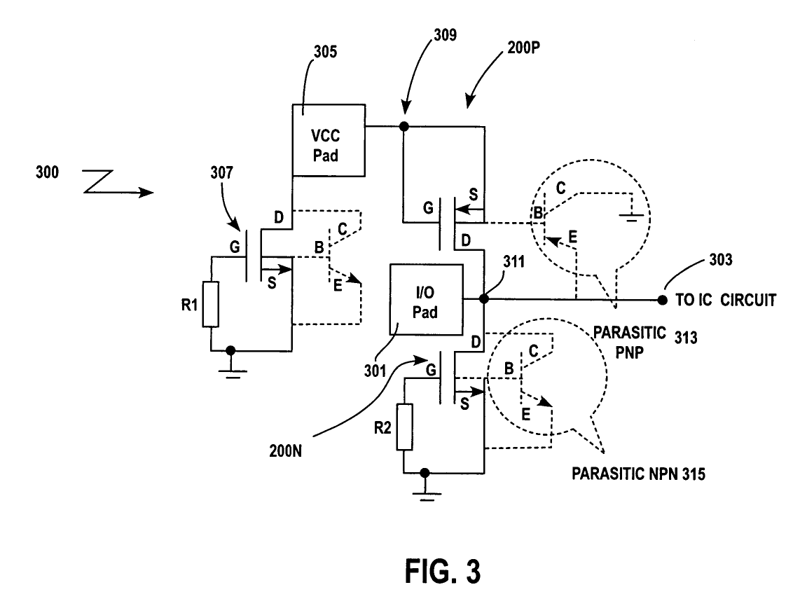

Another embodiment is depicted by the structure 400 of FIG. 4 employing a diode such as taught by Husher, supra. It has been found that altering such known structures enhances ESD protection. A surface diode element is formed by surface metal 401 and the neighboring contacted N+ doped regions 403, 405 forming the cathode and anode in the P-well 209 of the P-epi layer 205. Note that the N+ doped regions 403, 405 also form the drains of a pair of traditional N-channel MOSFETs 407, 409. From FIG. 3 it can be seen that a ESD input spike to the I/O pad 301 is connected to the drains of the push-pull MOSFETs 200P, 200N at their respective drain, D, contacts. A P-deep region 425 is implanted between the adjacent N+ doped regions 403, 405, preferably extending into the P-well 209 to a depth at least equal to or preferably greater than the depth of the N+ doped regions. The dimensions of the P-deep region 425 can be designed to specific implementations for tailoring the breakdown voltage. An ESD spike will thus allow a diode breakdown through the P-well 209 to the P-epi/P-substrate 205, 201 before affecting the MOSFETs. Since the surface concentration of an implant region is highest as the surface 205′, by moving the P-deep region 405 higher in the structure, namely to abut the epitaxial layer 205 surface 205′, a lower breakdown voltage will be provided.

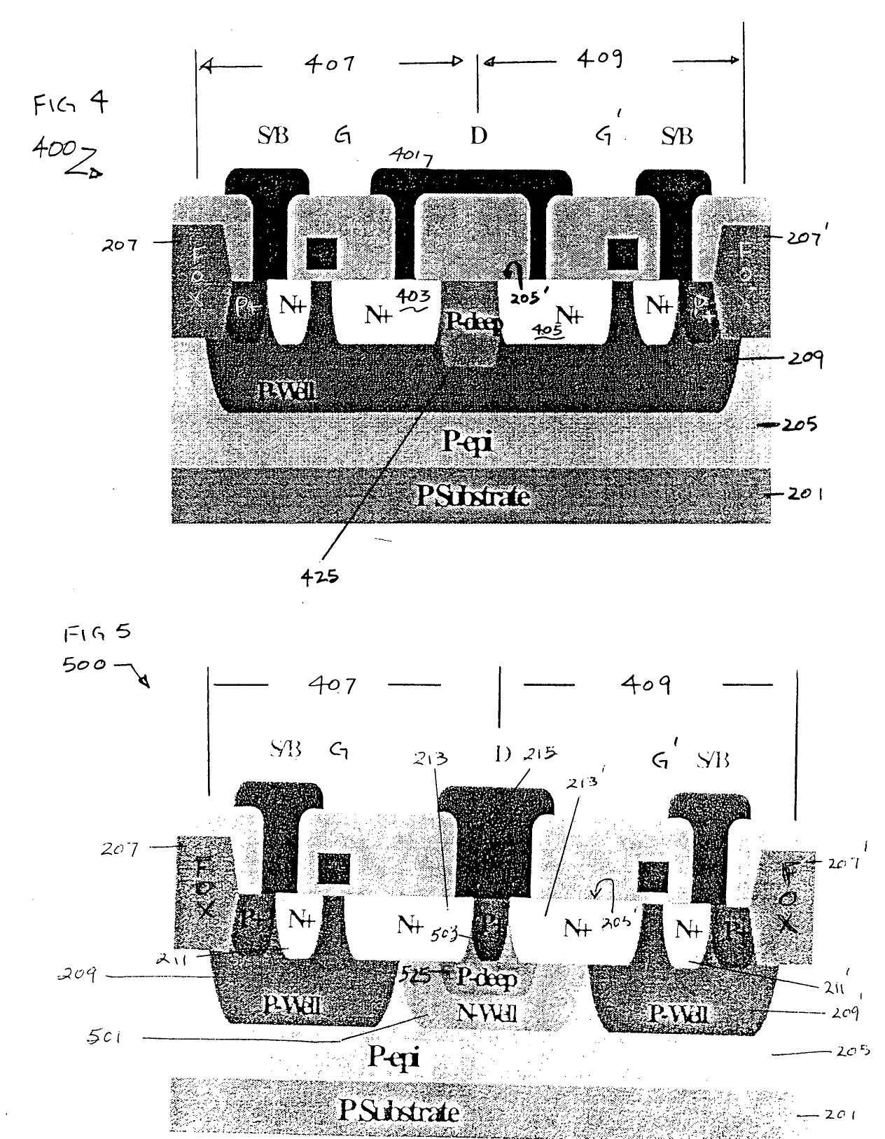

FIG. 5 is another embodiment of the present invention. The structure 500 depicts an arrangement of N-MOSFETs with integrated silicon controlled rectifier (“SCR”). A pair 407, 409 of drain-connected N-channel MOSFETs (see also FIG. 2A, FIG. 4) structure 500 is formed to include an N-well 501 segregating respective P-wells 209, 209′ of the N-MOSFETs 407, 409; compare also to FIG. 1A.

In this embodiment, a P-deep region 525 is formed subjacent the drain regions 213, 213′ and within the N-well 501. Note that this forms a parasitic PNP transistor using the P-deep region 525 as an emitter, the N-well 501 as a base, and the P-well/epi/P-substrate layers 205/201 as a collector. P-deep region 525 dimensions can be tailored to achieve the desired SCR punch-through voltage based on the specific implementation requirements, tuning the breakdown fields and improving the PNP transistor gain accordingly.

NPN transistors are formed using each N+ source 211, 211′ as an emitter, each P-well 209, 209′ as a base, and the drain N-well 501 as a collector. These two bipolar transistors thus form an SCR between the drain and source of each N-channel MOSFET. The addition of the P-deep region 525 in the N-well 501 has the effect of increasing the PNP transistor gain. Note also that the ESD breakdown voltage, or in this case punch-through voltage of the SCR, can be controlled by the spacing between the P-deep region 525 and P-wells 209, 209′, i.e., reduced by reducing the spacing and by depth of the P-deep region implant into the N-well 501. In operation, during a positive ESD spike, +Ve, to the I/O pad 301, FIG. 3, the SCR being in parallel with the N-channel MOSFETs can conduct a significant amount of current, enhancing ESD protection.

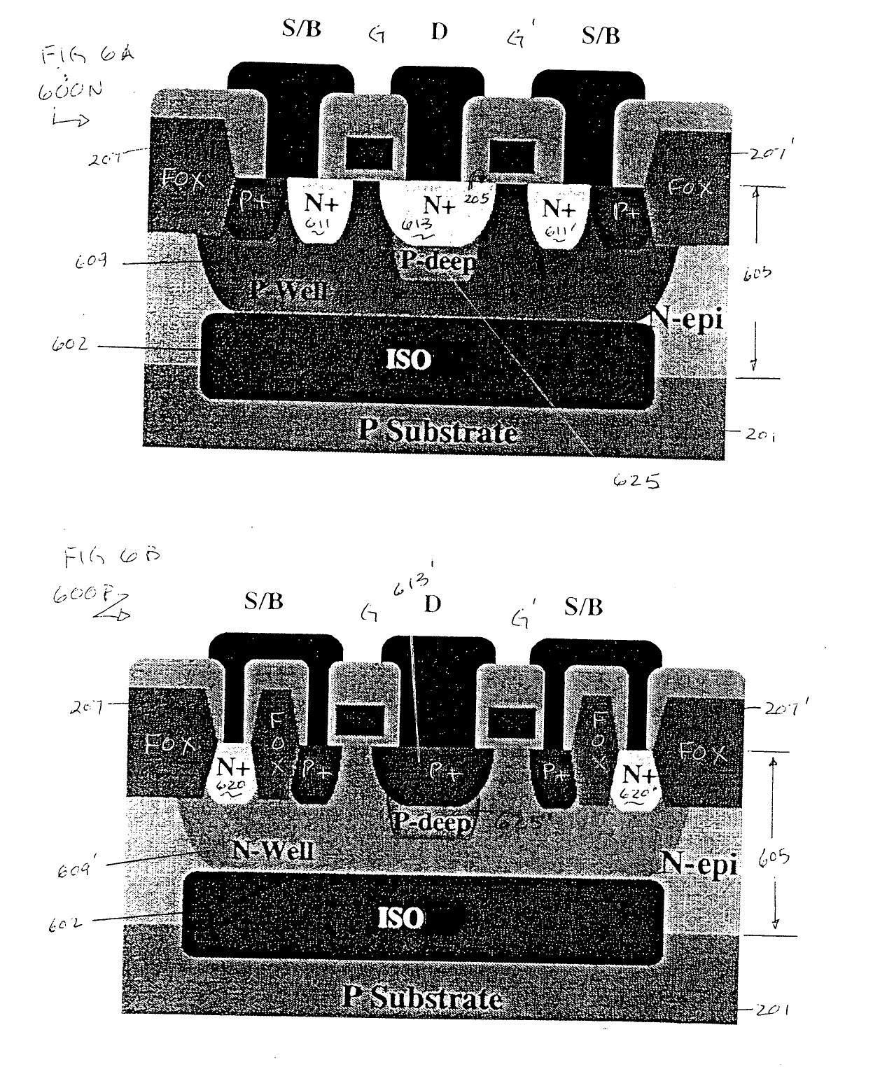

FIGS. 6A and 6B illustrate the concept of the present invention in BiCMOS technology exemplary embodiments. While a N-type epitaxial layer 605 is shown in both, it will be recognized by those skilled in the art that P-type epitaxial layer implementations are known. These structures employ a buried isolation layer, or region, 602 as is also known in the art. In FIG. 6A, for N-MOSFET construction, a parasitic lateral NPN transistors (see FIG. 3, 315)—from the N+ type doped drain region 613 forming the NPN collector, the MOSFET body region, P-well 609, forming the NPN base, and the N+ type doped source regions 611, 611′ forming the grounded emitter—is provided with an increased gain during breakdown by the addition of the P-deep region 625 subjacent the drain region 613 in the P-well 609.

In FIG. 6B, for P-MOSFET construction, a parasitic PNP transistor (see FIG. 3, 313)—from the P+ type doped drain region 613′ forming the emitter, the N-well/body 609′ and N+ doped region 620 forming the base, and the grounded P-substrate 201 forming the collector—is provided with increased gain by the addition of the P-deep region 625′ in the N-well 609′ subjacent the P+ doped drain 613′. Note that the buried isolation layer 602 under the P-channel MOSFET reduces the collector resistance and proximity to the P-deep region 625′ increases the gain of the PNP transistor.

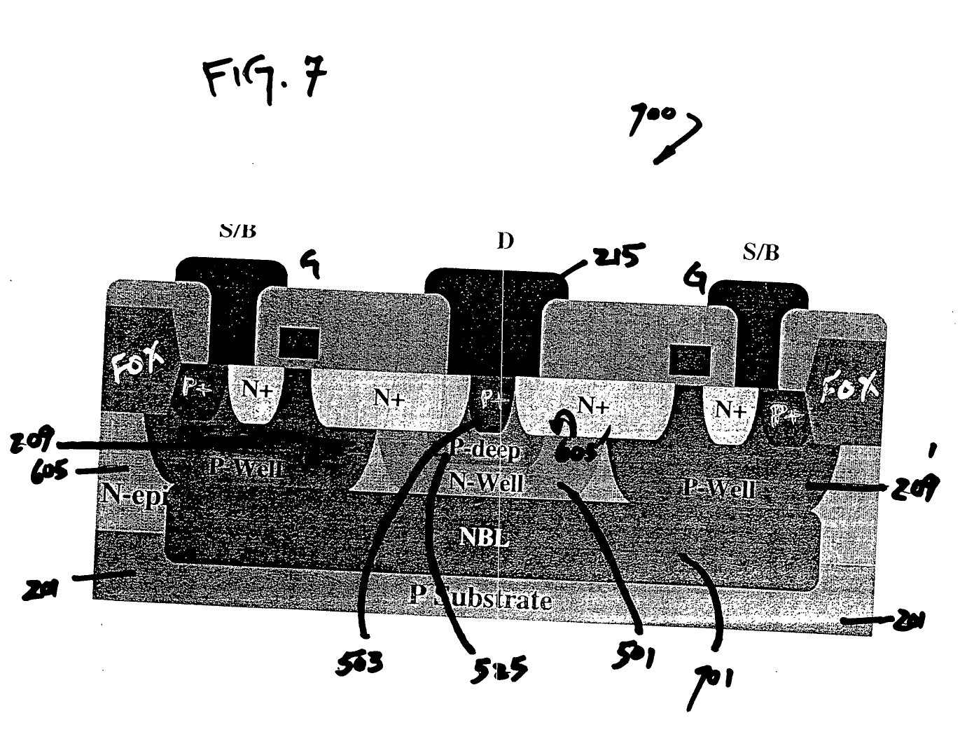

FIG. 7 is a representation of a BiCMOS technology structure 700 for a push-pull I/O circuit with enhanced ESD protection. An N-MOSFET pair incorporating a SCR (see also FIG. 5) is again provided with a P-deep region 525 subposing the drain contact 215. Here note that an N-type doped buried layer (“NBL”) 701 pinches the P-well regions 209, 209′. This causes the P-well resistance to be higher, resulting in a faster turn-on of the SCR. As with the previous embodiments, particularly that of FIG. 5, the added P-deep region 525 increases parasitic transistor gain accordingly, enhancing ESD protection performance.

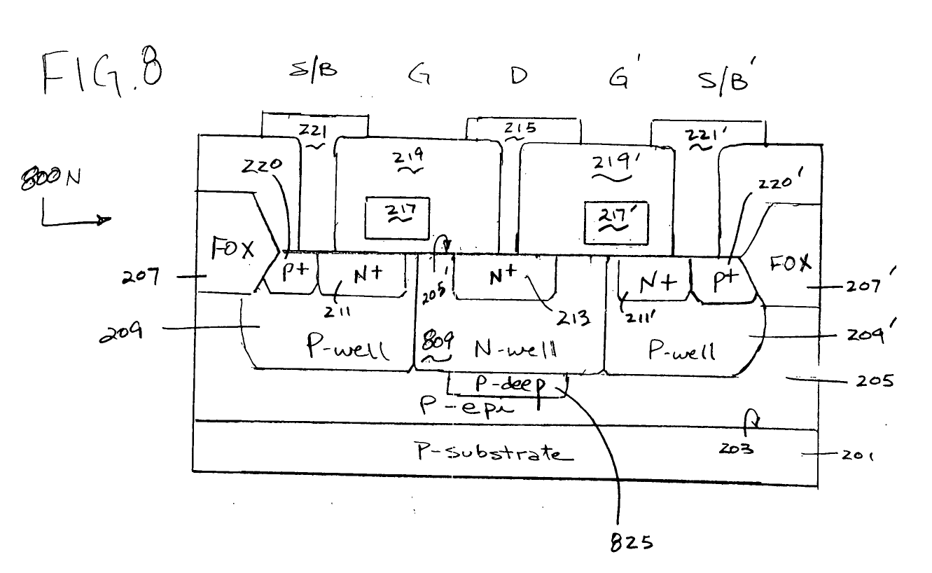

FIG. 8 is a cross-sectional, elevation view, schematic of an extended drain N-channel MOSFET structure in another exemplary embodiment of the present invention. Extended and enhanced drain region devices, having reduced on-resistance without significantly reducing breakdown voltage, are known, such as from common assignees U.S. Pat. No. 5,517,046, filed by Hsing et al. for HIGH VOLTAGE LATERAL DMOS DEVICE WITH ENHANCED DRIFT REGION, incorporated herein by reference. As with prior embodiments herein, a P-deep region 825 subjacent the N-well 809 containing the drain region 213. Note that it should be recognized by those skilled in the art that the P-wells 209, 209′ can be P-body regions in a DMOS implementation such as in Hsing et al. As with the embodiment described with respect to FIG. 2A, there is a higher drain-to-substrate inherent capacitance and enhanced parasitic NPN transistor gain in breakdown of the structure compared to FIG. 1A, providing a lower trigger voltage for the N-MOSFETs, and enhancing ESD protection.

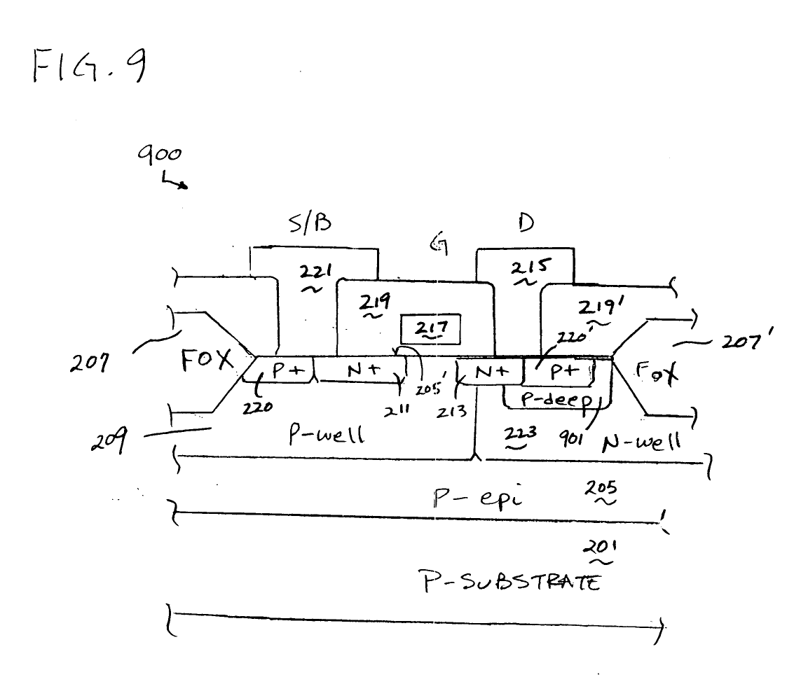

FIG. 9 is a cross-sectional, elevation view, schematic of a single N-MOSFET structure in another exemplary embodiment in accordance with the present invention. In some ICs, such as for power chips, it is known to have relatively large arrays of single MOSFET structures 900 in an array configuration. It is possible in accordance with the present invention to provide each individual MOSFET structure 900 with a P-deep region 901 such as illustrated. In this embodiment, the structure 900 is an example of a layout where the P-deep region 901 is implanted conveniently in association with the drain, D, region. It should be expected that when using implant technology for forming the P-deep region 901 that the ion concentration will migrate toward the surface, shown as forming a surface 205′ concentration abutting the field oxide isolation 207′ for the drain region. Again, as with the embodiment described with respect to FIG. 2A, there is a higher drain-to-substrate inherent capacitance and enhanced parasitic NPN transistor gain in breakdown of the structure compared to FIG. 1A, providing a lower trigger voltage for the N-MOSFETs, and enhancing ESD protection.

The foregoing Detailed Description of exemplary and preferred embodiments is presented for purposes of illustration and disclosure in accordance with the requirements of the law. It is not intended to be exhaustive nor to limit the invention to the precise form(s) described, but only to enable others skilled in the art to understand how the invention may be suited for a particular use or implementation. The possibility of modifications and variations will be apparent to practitioners skilled in the art. Particularly, other MOS and BiCMOS structures can be made by other arrangements wherein regional dopant types are reversed to configure complementary structures. No limitation is intended by the description of exemplary embodiments which may have included tolerances, feature dimensions, specific operating conditions, engineering specifications, or the like, and which may vary between implementations or with changes to the state of the art, and no limitation should be implied therefrom. Applicant has made this disclosure with respect to the current state of the art, but also contemplates advancements during the term of the patent, and that adaptations in the future may take into consideration those advancements, in other word adaptations in accordance with the then current state of the art. It is intended that the scope of the invention be defined by the claims as written and equivalents as applicable. Reference to a claim element in the singular is not intended to mean “one and only one” unless explicitly so stated. Moreover, no element, component, nor method or process step in this disclosure is intended to be dedicated to the public regardless of whether the element, component, or step is explicitly recited in the claims. No claim element herein is to be construed under the provisions of 35 U.S.C. Sec. 112, sixth paragraph, unless the element is expressly recited using the phrase “means for . . . ” and no method or process step herein is to be construed under those provisions unless the step, or steps, are expressly recited using the phrase “comprising the step(s) of . . . .”

1. A semiconductor MOSFET structure having improved electrostatic discharge tolerance, the structure comprising:
a semiconductor substrate having an active device surface;
in said surface, a MOSFET source region and a MOSFET drain region separated by a channel region;
a P-type dopant region subjacent said drain region and having a dopant concentration and predetermined dimensions such inherent parasitic transistor gain of said MOSFET structure is increased.

2. The structure as set forth in claim 1 comprising:
said MOSFET is a N-channel MOSFET wherein said P-type dopant region has said dopant concentration and said predetermined dimensions set for increasing drain-to-substrate capacitance thereby.

3. The structure as set forth in claim 1 comprising:
said MOSFET is a N-channel MOSFET wherein said P-type dopant region has said dopant concentration and said predetermined dimensions set such that the MOSFET trigger voltage is decreased thereby.

4. The structure as set forth claim 1 wherein breakdown voltage of said parasitic transistor is tailored by depth of the P-type dopant region with respect to said surface and said substrate.

5. The structure as set forth in claim 1 wherein said MOSFET is a N-channel MOSFET located in a P-type dopant well in said epitaxial layer and surface concentration of the dopant ions in the P-deep region is approximately an order of magnitude greater than that of the dopant ions at the P-well 209 surface concentration.

6. The structure as set forth in claim 3 comprising:
a pair of MOSFETs, including a N-MOSFET, and a P-MOSFET, wherein said N-MOSFET and said P-MOSFET are connected in a push-pull configuration.

7. The structure as set forth in claim 6 wherein the P-deep implant region in both the P-MOSFET and the N-MOSFET reduces effective base width of parasitic transistors therein via reduction of substrate-to-drain spacing.

8. An integrated circuit electrostatic discharge protection device for an IC Input-output pad, the device comprising:
a N-MOSFET;
a P-MOSFET, wherein said N-MOSFET and P-MOSFET are connected in a push-pull configuration with drain regions thereof connected to said Input-output pad; and
both said N-MOSFET and said P-MOSFET including a P-type dopant region substantially subjacent respective the drain regions of each such that P-MOSFET parasitic PNP transistor gain and N-MOSFET parasitic NPN transistor gain is increased thereby.

9. An electrostatic discharge protection circuit for an IC having at least one I/O pad and at least one VCC pad having a electrically grounded electrostatic discharge protection device connected thereto, the circuit comprising:
a N-GCMOSFET having a first drain region connected to said I/O pad, a first gate region connected to electrical ground, and a first source region connected to electrical ground; and
a P-GCMOSFET having a second drain region connected to said I/O pad, a second gate region connected to said VCC pad, and a second source region connected to said VCC pad,
wherein said first drain region has a P-type dopant region substantially subjacent thereto for enhancing parasitic NPN transistor gain thereof, and said second drain region has a P-type dopant region substantially subjacent thereto for enhancing parasitic PNP transistor gain thereof.

10. The circuit as set forth in claim 9 wherein when the I/O pad experiences an electrostatic discharge event, the P-type drain, acting as the emitter, to source, acting as base, forms a diode of the P-GCMOSFET that gets forward biased such that a first part of Electrostatic discharge event current is shunted to ground via the P-epi and substrate layers; a second part of the electrostatic discharge event current is shunted through the parasitic PNP transistor of the GC-MOSFET to ground via the electrostatic discharge protection device on the VCC pad as its parasitic NPN transistor is turned ON; a third part of the Electrostatic discharge event current flows through N-GC-MOSFET, and a parasitic NPN transistor of GC-MOSFET turns on during an electrostatic discharge event and the third part of the electrostatic discharge current is shunted to ground.

11. A N-channel MOSFET structure for electrostatic discharge device, the structure comprising:
a P-doped substrate having an epitaxial layer for forming active device elements therein; and
within said epitaxial layer,
a N+ doped source region,
a N+ drain region,
a P-doped channel region between the source region and the drain region,
a gate superjacent the channel,
an N-doped well region beneath said drain region having a width dimension less than a width dimension of said drain region, and
a P-doped deep region, beneath said drain region and adjacent said well region, having a dopant concentration greater than said P-doped channel region,
wherein said P-doped deep region increases gain of a parasitic lateral NPN transistor formed by said source region, said channel region and said drain region and lowers triggering voltage of said MOSFET.

12. A P-channel MOSFET structure for an electrostatic discharge protection circuit, the structure comprising:
a P-doped substrate having an epitaxial layer;
an N-doped well in said epitaxial layer for forming active device elements therein; and
within said N-doped well,
a P+ doped source region,
a P+drain region,
a N-doped channel region between the source region and the drain region,
a gate superjacent the channel, and
a P-doped deep region, beneath said drain region and adjacent said well region,
wherein said P-doped deep region increases gain of a parasitic PNP transistor formed by said drain region, N-doped well region and said epitaxial layer and lowers triggering voltage of said MOSFET.

13. A MOSFET structure for an electrostatic discharge protection circuit, the structure comprising:
a substrate having an epitaxial layer forming an active device surface;
at least two MOSFETs proximate said surface, each MOSFET having a first dopant type drain region wherein said drain regions are adjacent and separated by a region of said surface and forming diode poles thereby; and
a second dopant type deep region at said region of the surface, wherein said deep region has a depth from said surface into said epitaxial layer greater than a depth of each of said drain regions such that an electrostatic discharge spike causes a diode breakdown to the epitaxial layer before affecting the MOSFETs.

14. The structure as set forth in claim 13 wherein said deep region has a predetermined P-type ion concentration and predetermined dimensions such that an electrostatic discharge spike at said drain will cause a diode breakdown through epitaxial layer and substrate before affecting the MOSFETs.

15. A MOSFET structure for an electrostatic discharge protection circuit employing an SCR, the structure located in an epitaxial layer of a first dopant type of a substrate, said epitaxial layer having an active device surface, the structure comprising:
a first MOSFET of a second dopant type located proximate said surface and having a first drain region of the second dopant type;
a second MOSFET of the second dopant type and located proximate said surface and having a second drain region of the second dopant type proximate said first drain region;
a drain contact electrically connecting said first drain region and said second drain region;
a surface contact region abutting said drain contact and separating said first drain region said second drain region, said surface region having said first dopant type;
subjacent the surface contact region and within said epitaxial layer, a well of said second dopant type, wherein said well is subjacent both said first drain region and said second drain region; and
within said well, a deep region of P-type ion dopant, wherein said deep region is subjacent both said first drain region, said second drain region, and said surface contact region,
wherein said deep region dimensions and concentration of the P-type ion are predetermined for achieving a desired SCR punch-through voltage via tuning breakdown fields and improving structure inherent bipolar transistor gain accordingly.

16. The structure as set forth in claim 15 wherein punch-through voltage of the SCR is controlled by the spacing between the deep region and P-wells.

17. The structure as set forth in claim 15 wherein during a positive electrostatic discharge spike to an I/O pad associated with the structure, the SCR being in parallel with the N-channel MOSFETs conduct a significant amount of current, enhancing electrostatic discharge protection.

18. A BiCMOS technology N-MOSFET structure for electrostatic discharge protection circuits, the structure comprising:
a P ion doped substrate;
an N ion doped epitaxial layer superjacent said substrate, said epitaxial layer having an upper surface distal from said substrate;
a buried isolation layer;
a P ion doped well subjacent in said upper surface;
a N+ ion doped source region subjacent said surface;
a N+ ion doped drain region subjacent said surface;
a region of said well forming a P ion channel region at said surface between said source region and said drain region;
a gate structure superposing said channel region; and
subjacent said drain region and within said well, a P ion doped deep region, said deep region having an ion concentration greater than ion concentration of said well,
such that lateral bipolar parasitic NPN transistor of said structure is provided with increased gain by the deep region.

19. A BiCMOS technology P-MOSFET structure for electrostatic discharge protection circuits, the structure comprising:
a P ion doped substrate;
an N ion doped epitaxial layer superjacent said substrate, said epitaxial layer having an upper surface distal from said substrate;
a buried isolation layer;
a N ion doped well subjacent in said upper surface;
a P+ ion doped source region subjacent said surface;
a P+ ion doped drain region subjacent said surface;
a region of said well forming a N ion channel region at said surface between said source region and said drain region;
a gate structure superposing said channel region; and
subjacent said drain region and within said well, a P ion doped deep region, said deep region having an ion concentration substantially equal to or greater than ion concentration of said drain region,
such that vertical bipolar parasitic PNP transistor of said structure is provided with increased gain by the deep region.

20. A BiCMOS technology structure for a push-pull Input-output electrostatic discharge protection circuit employing an SCR, the structure located in an epitaxial layer of a first dopant type of a substrate of a second dopant type, said epitaxial layer having an active device surface, the structure comprising:
a first dopant type buried layer segregating said epitaxial layer and said substrate;
a second dopant type first well within said epitaxial layer and subjacent said surface;
a second dopant type second well within said epitaxial layer and subjacent said surface;
a first dopant type third well within said epitaxial layer and subjacent said surface, such that third well is adjacently between said first well and said second well;
a first MOSFET of the first dopant type located within said first well proximate said surface and having a first drain region of the first dopant type and having a predetermined drain width for superjacently spanning a first area of said surface encompassing surface regions of both said first well and said third well;
a second MOSFET of the first dopant type and located within said second well proximate said surface and having a second drain region of the first dopant type and having a predetermined drain width for superjacently spanning a second area of said surface encompassing surface regions of both said third well and said second well;
a drain contact electrically connecting said first drain region and said second drain region;
a surface contact region abutting said drain contact and separating said first drain region said second drain region, said surface region having said second dopant type;
within said third well, a deep region of P-type ion dopant, wherein said deep region is subjacent both said first drain region, said second drain region, and said surface contact region,
wherein said deep region dimensions and concentration of the P-type ion are predetermined for achieving a desired SCR punch-through voltage via tuning breakdown fields and improving structure inherent bipolar transistor gain accordingly.

21. An extended drain N-channel MOSFET structure comprising:
a P-type substrate;
in said substrate at least one MOSFET structure having extended and enhanced drain region devices for providing reduced on-resistance at a surface region of said substrate, said MOSFET structure including an N+ doped drain region in an N-type well region; and
a P-deep region subjacent the N-well containing the drain region, said P-deep region having geometry and a dopant concentration such that said P-deep region increases gain of a parasitic lateral NPN transistor and lowers triggering voltage of said MOSFET, improving electrostatic discharge tolerance thereby.
